(19) United States
(12) Patent Application Publication
(10) Pub. No.: US 2007/0176281 A1
(43) Pub. Date: Aug. 2, 2007

(54) Semiconductor package

(75) Inventors: Ki-Don Kim, Seoul (KR); Jae-Seon An, Kyunggi-Do (KR); Seong-Chul Choi, Kyunggi-Do (KR); Seong-Eun Sim, Kyunggi-Do (KR); Hyun-Kyu Lee, Kyunggi-Do (KR); Su-Jin Lim, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/698,884

(22) Filed: Jan. 29, 2007

(30) Foreign Application Priority Data
Jan. 27, 2006 (TW) 95103629

(51) Int. Cl. H01L 23/12

(52) U.S. Cl. 257/700; 257/E23.067

(57) ABSTRACT

A semiconductor package includes a substrate having a plurality of through holes for interconnecting electrically conductive traces formed on upper and lower surfaces of the substrate. The through holes are classified into a first set of through holes and a second set of through holes. The second set of through holes is located exterior of the first set of through holes, and surrounds the first set of through holes. A die is mounted on the upper surface of the substrate and is connected electrically to the first set of through holes. A metal shield is disposed on the substrate for enclosing the die therein and is connected electrically to the second set of through holes. A molding resin encapsulates the metal shield, the die on the substrate and fills a gap confined between the metal shield and the die.

### FIELD OF THE INVENTION

The invention relates to a semiconductor package, and more particularly to a semiconductor package that can lower the possibility of operation disruption by nearby EMI (electromagnetic interference) or electromagnetic field.

### BACKGROUND OF THE INVENTION

An electromagnetic field (EM field) caused by a first electronic device may result in the disruption of operation of a second electronic device when the second electronic device is in the vicinity of the first electronic device. Such a phenomenon is generally called EMI (electromagnetic interference) and affects the electronic device in two ways, i.e. radiation and conductive transmission. An EMI source may transmit the noise to a recipient by coupling over the air in the radiation form. Alternately, the EMI source may transmit the noise to the recipient by coupling via the conductive material (such as cables or wires).

The problem of EMI is aggravated in the wireless communication system or high radiating frequency system. A built-in chip module in a wireless communication device is provided with several densely located integrated circuits according to the increased function abilities so that adjacent circuit traces are spaced apart from one another at a relatively small distance. Several dies with different function ability can be disposed on the same substrate together with other electronic components. The whole assembly is undergone a packing operation in order to achieve a semiconductor package including a multi-chip module with multi-function ability.

As mentioned above, during the operation, the dies in the semiconductor package may be disrupted by EMI due to the short-distance arrangement of the traces and the electromagnetic radiation or noise caused thereby is transmitted from one to another die over the circuit traces of the substrate. The more the dies in the semiconductor package, the severer the interference is resulted and is interacted among the dies, thereby worsening the operation function.

For those skilled in the art and the manufacturers, the problem to effectively reduce the disruption of the operation of a semiconductor package within an electronic communication device or high radiating frequency system becomes a major task to be solved at present.

### SUMMARY OF THE INVENTION

The object of the present invention is to provide a semiconductor package that has a unique structure capable of protecting itself from being disrupted by the EMI.

According to the present invention, a semiconductor package is provided to include a substrate, a die, a metal shield and a molding resin. The substrate has a plurality of through holes for interconnecting electrically conductive traces formed on upper and lower surfaces of the substrate. The through holes are classified into a first set of through holes and a second set of through holes. The second set of through holes is located exterior of the first set of through holes, and surrounds the first set of through holes. The die is mounted on the upper surface of the substrate and is connected electrically to the first set of through holes. The metal shield is disposed on the upper surface of the substrate for enclosing the die therein and is connected electrically to the second set of through holes. The metal shield is further connected to a common voltage source so as to protect the die from being disrupted by electromagnetic interference. The molding resin encapsulates the metal shield on the substrate and fills a gap confined between the metal shield and the die.

### BRIEF DESCRIPTION OF THE DRAWING

Other features and advantages of this invention will become more apparent in the following detailed description of the preferred embodiments of this invention, with reference to the accompanying drawings, in which:

FIG. 1 is an exploded view of a first embodiment of a semiconductor package of the present invention;

FIG. 2 is a sectional view of the first embodiment of the semiconductor package of the present invention; and

FIG. 3 is a sectional view of a second embodiment of the semiconductor package of the present invention.

### DETAILED DESCCRIPTIONS OF THE PREFERRED EMBODIMENTS

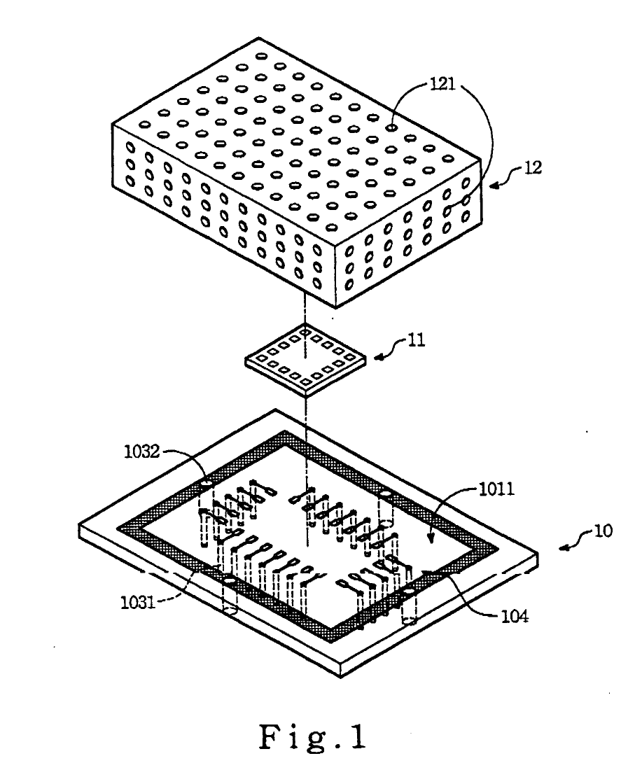

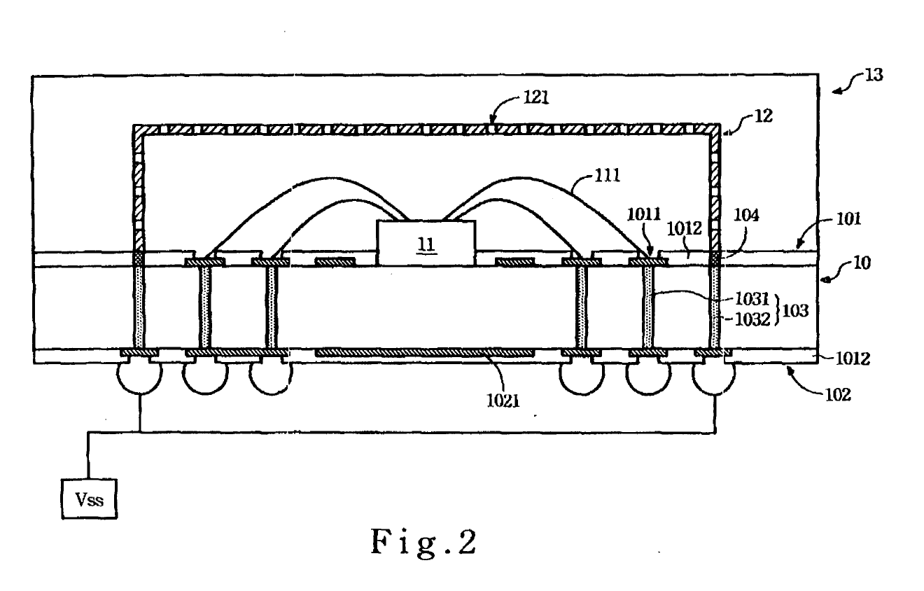

FIGS. 1 and 2 show exploded and sectional views of a first embodiment of a semiconductor package of the present invention. The semiconductor package includes a substrate 10, a die 11, a metal shield 12 and an encapsulating body 13 (herein after called a molding resin).

The substrate 10 is formed for carrying different dies thereon. The substrate 10 has an upper surface 101, a lower surface 102 opposite to the upper surface 101, and a plurality of through holes 103 for electrically interconnecting the conductive traces formed on the upper and lower surface 101, 102. Interconnection of the conductive traces by the through holes 103 is known in the art and a detailed description is omitted herein for the sake of brevity.

Two metal layers (such as copper alloy layers) are disposed on the upper and lower surfaces 101, 102 of the substrate 10 and are patterned to form upper and lower circuit patterns 1011, 1021 defining the aforementioned conductive traces for signal transmission. A solder resistant layer 1012 is coated onto a respective conductive trace and formed with a plurality of openings at predetermined positions in order to expose predetermined sections of the conductive traces.

The through holes 103 can be classified into a first set of through holes 1031 and a second set of through holes 1032 due to different connection purposes. The through holes 1031 of the first set interconnect the respective conductive traces of the upper and lower circuit patterns 1011, 1021. The through holes 1032 of the second set are located exterior of the first set of through holes 1031 and surround the first set of through holes 1031. Therefore, the through holes 1032 of the second set are not electrically connected to the conductive traces of the upper and lower circuit patterns 1011, 1021.

In this embodiment, solder pads or pins can be fixed to the lower surface of the substrate in contact with the bottom edges of the first or second set of through holes 1031, 1032 for facilitating signal communication with other electronic device depending on the requirements of the semiconductor package.

The die 11 is mounted on the upper surface of the substrate 10 and is connected electrically to the first set of through holes 1031, as shown in FIG. 2. Several bonding wires 111 are used for interconnecting electrically the input/output contacts of the die 11 and the conductive traces of the upper circuit pattern 1011. The die 11 is further connected electrically to the conductive traces of the lower circuit pattern 1021 via the first set of through holes 1031. In other embodiment, the die 11 is flip chip and connected to the conductive traces of the upper circuit pattern 1011 and the first set of through holes 1031.

The metal shield 12 is disposed on the upper surface of the substrate 10 for enclosing the die 11 therein and is connected electrically to the second set of through holes 1032. The metal shield 12 is a cap structure having a top wall and four sidewalls extending downwardly from the top wall to enclose the die 12 therein.

Several methods can be used for interconnecting the metal shield 12 and the second set of through holes 1032. In one embodiment, the upper surface of the substrate 10 is etched to form a looped groove that surrounds the conductive traces. A metal, such as silver or copper, is filled into the looped groove to form a circuit ring 104.

The circuit ring 104 is disposed on the upper surface of the substrate 10 and surrounds the conductive traces of the upper circuit pattern 1011. However, the corresponding conductive traces can still be connected to the circuit ring 104 if circumstance required. In case there exists a multi-chip module in the semiconductor package, the presence of the circuit ring 104 on the substrate 10 may lower the possibility of disruption by the EMI among the dies.

The second set of through holes 1032 is located below the circuit ring 104. In fact, the circuit ring 104 is rectangular and has four lower sides respectively provided with metal plugs for electrically contacting the second set of the through holes 1032. The bottom edge of the metal shield 12 is disposed on the circuit ring 104 in an overlap manner.

In another embodiment, a solder layer (not shown in the drawing) can be coated on the outer surface of the circuit ring 104 such that the solder layer is later connected to the metal shield 12 via a soldering process.

In still another embodiment, each of the sidewalls has a bottom edge. The metal sψ ield 12 further has four protrusions projecting downwardly and respectively from the bottom edges of the sidewalls to contact the circuit ring 104, which, in turn, is coupled electrically to the second set of through holes 1032. Alternately, the protrusions of the metal shield 12 can be coupled directly to the second set of through holes 1032.

The metal shield 12 can further be connected electrically to a common voltage source Vss via the second set of through holes 1032 so as to protect the die 11 from being disrupted by the electromagnetic interference.

The metal shield 12 is formed with at least one opening so that during the molding process, the molding resin 13 firstly encapsulates the metal shield 12, later the die 11 on the substrate 10 and simultaneously fills a gap confined between the metal shield 12 and the die 11. In one embodiment, the top wall of the metal shield 12 is formed with a plurality of openings 121 to enhance the molding process. Each of the sidewalls of the metal shield 12 is formed with a plurality of openings 121. The formation of the openings 121 in the top wall and the sidewalls accelerates the filling rate of the gap by the molding resin 13.

An important to note is that since the metal shield 12 above the die 11 is connected to the common voltage source Vss via the second set of through holes 1032, serving as the electrical ground system and providing stable low voltage to the semiconductor package of the present invention. Thus, the metal shield 12, the circuit ring 104 and the electrical ground system cooperatively provide electrical shielding effect to protect the die 11 from being disrupted. The electromagnetic fields caused by one electronic device have small influence on the die in the present semiconductor package.

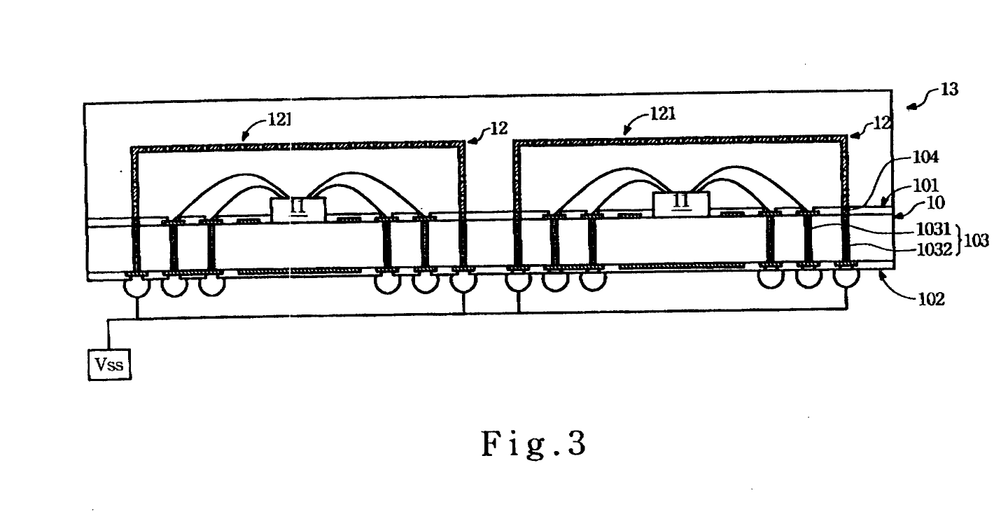

Referring to FIG. 3, a sectional view of the second embodiment of the semiconductor package of the present invention is shown and has the structure similar to the previous embodiment. The second embodiment includes multichip module having two dies 11 with different function abilities disposed on the same substrate 10. Each of the dies 11 is covered by the respective metal shield 12 and the respective circuit ring 14 such that the operation of one die is protected from being disrupted by the electromagnetic fields caused by the nearby die 11.

In short, it is relatively easy to fabricate the semiconductor package of the present invention. After disposing the circuit ring on the upper surface of the substrate, four plugs can be employed serving as the second set of through holes for electrically connecting the metal shield to the common voltage source so as to form an electrical ground system. The semiconductor package has a relatively large shielding effect to protect itself from being disrupted by EMI.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A semiconductor package comprising:
a substrate having a plurality of through holes for interconnecting electrically conductive traces formed on upper and lower surfaces of said substrate, said through holes being classified into a first set of through holes and a second set of through holes, said second set of through holes being located exterior of said first set of through holes and surrounding said first set of through holes;
a die mounted on said upper surface of said substrate and connected electrically to said first set of through holes;
a metal shield disposed on said upper surface of said substrate for enclosing said die therein and connected electrically to said second set of through holes, said metal shield further adapted to be connected to a common voltage source so as to protect said die from being disrupted by electromagnetic interference; and
a molding resin for encapsulating said die and said metal shield on said substrate and filling a gap confined between said metal shield and said die.

2. The semiconductor package according to claim 1, further comprising:
a circuit pattern disposed on said upper surface of said substrate; and
a plurality of bonding wires for interconnecting electrically said die and said circuit pattern.

3. The semiconductor package according to claim 2, wherein said circuit pattern is connected electrically to said first set of through holes.

4. The semiconductor package according to claim 1, wherein said metal shield has a bottom edge and a plurality of protrusions that project outwardly from said bottom edge and that are coupled electrically to said second set of through holes.

5. The semiconductor package according to claim 1, wherein said metal shield has a bottom edge, the semiconductor package further comprising a circuit ring that is coupled to said second set of through holes and said bottom edge of said metal shield.

6. The semiconductor package according to claim 5, wherein said bottom edge of said metal shield is disposed on said circuit ring in an overlap manner.

7. The semiconductor package according to claim 1, wherein said metal shield is formed with an opening to permit extension of said molding resin in order to fill said gap confined between said metal shield and said die.

8. The semiconductor package according to claim 1, wherein said metal shield is a cap structure having a top wall and four sidewalls extending downwardly from said top wall to enclose said die therein.

9. The semiconductor package according to claim 8, wherein said top wall of said metal shield is formed with a plurality of openings.

10. The semiconductor package according to claim 8, wherein each of said sidewalls of said metal shield is formed with a plurality of openings.

11. The semiconductor package according to claim 8, wherein each of said sidewalls has a bottom edge, said metal shield further having four protrusions projecting downwardly and respectively from said bottom edges of said sidewalls to couple electrically to said second set of through holes.

12. The semiconductor package according to claim 1, further comprising a solder layer disposed between said metal shield and said substrate for interconnecting said metal shield and said substrate together.

13. The semiconductor package according to claim 1, wherein said first and second sets of through holes are insulated from each other.
